(19) United States
(12) Patent Application Publication
(10) Pub. No.: US 2007/0290899 A1
(43) Pub. Date: Dec. 20, 2007

(54) DATA CODING

(76) Inventor: Donald Martin Monro, Beckington (GB)

Correspondence Address: STERNE, KESSLER, GOLDSTEIN & FOX P.L.L.C., 1100 NEW YORK AVENUE, N.W., WASHINGTON, DC, 20005, US

(21) Appl. No.: 11/425,142

(22) Filed: Jun. 19, 2006

(51) Int. Cl. H03M 7/34

(52) U.S. Cl. 341/51

(57) ABSTRACT

Briefly, in accordance with one embodiment, a method of coding data is described.

### FIELD

The present patent application is related to data coding.

### BACKGROUND

As is well-known, efficient data coding for storage or transmission continues to be an area in which new approaches are sought. For example, if data may be coded more efficiently, such as by compression, the amount of memory to store data to be coded may be reduced. Likewise, in communications systems, if data may be coded efficiently, for a communications channel of a given bandwidth, for example, potentially more information may be transmitted in a given unit of time. These goals and many others may be the object of methods for efficient coding of data.

### BRIEF DESCRIPTION OF THE DRAWINGS

Subject matter is particularly pointed out and distinctly claimed in the concluding portion of the specification. Claimed subject matter, however, both as to organization and method of operation, together with objects, features, and advantages thereof may best be understood by reference of the following detailed description if read with the accompanying drawings in which:

FIG. 1 is a diagram and table illustrating one embodiment of a Huffman code; and

FIG. 2 is a diagram and table illustrating an embodiment of data coding, such as, for example, in accordance with claimed subject matter.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, well-known methods, procedures, components and/or circuits have not been described in detail so as not to obscure claimed subject matter.

Some portions of the detailed description which follow are presented in terms of algorithms and/or symbolic representations of operations on data bits and/or binary digital signals stored within a computing system, such as within a computer and/or computing system memory. These algorithmic descriptions and/or representations are the techniques used by those of ordinary skill in the data processing arts to convey the substance of their work to others skilled in the art. An algorithm is here, and generally, considered to be a self-consistent sequence of operations and/or similar processing leading to a desired result. The operations and/or processing may involve physical manipulations of physical quantities. Typically, although not necessarily, these quantities may take the form of electrical and/or magnetic signals capable of being stored, transferred, combined, compared and/or otherwise manipulated. It has proven convenient, at times, principally for reasons of common usage, to refer to these signals as bits, data, values, elements, symbols, characters, terms, numbers, numerals and/or the like. It should be understood, however, that all of these and similar terms are to be associated with appropriate physical quantities and are merely convenient labels. Unless specifically stated otherwise, as apparent from the following discussion, it is appreciated that throughout this specification discussions utilizing terms such as “processing”, “computing”, “calculating”, “determining” and/or the like refer to the actions and/or processes of a computing platform, such as a computer or a similar electronic computing device, that manipulates and/or transforms data represented as physical electronic and/or magnetic quantities and/or other physical quantities within the computing platform's processors, memories, registers, and/or other information storage, transmission, and/or display devices.

One common way of coding data for transmission, which finds particular application at run time, is a by way of a Variable Length Coder (VLC). A variable length code is a widely-used method of reducing the “cost” of storing or sending a stream of symbols. It normally applies to situations in which probabilities of occurrence of possible symbols for a message are not equal, as is encountered in many typical applications. A Variable Length Code (VLC) makes substitutions for symbols in which short codes are used for frequently occurring symbols and longer codes for infrequent symbols. In this way, the average length of a code may be reduced. The best known general purpose VLC is referred to as the Huffman Code, but there are many others including the Fano/Shannon code. Details of the Huffman code may be found in Huffman, D: ‘A method for the constructions of minimum redundancy codes’, Pro. Inst. Radio Eng., 1952, 9, (40), pp 1098-1101. Of course, claimed subject matter is not limited in scope to the Huffman Code.

Morse code is also a VLC in that it substitutes short codes for frequently occurring letters like E (one dot) and longer ones for others like Q (dash dot dot dash). Another illustration is coding plain English text. In general, the letters of the alphabet occur with different frequencies. E is the most common symbol, followed in order by T A O I N S H R D L U. As these are not equally likely, an efficient binary code, for example, will assign fewer bits to E than to any other symbol.

Although claimed subject matter is not limited in scope in this respect, one example of a possible embodiment comprises a method of coding an alphabet of N symbols ranked by expected probability of occurrence, in which N is a positive integer numeral. Such a method embodiment may include: defining a threshold rank T, in which T is a positive integer numeral, for example; coding symbols which have a higher rank than T with a variable length code; and coding symbols which are ranked T or lower with a fixed length code, although, again this is simply an example and claimed subject matter is not limited in scope to this particular example. Of course, claimed subject matter is not limited in scope to employing symbols that, by convention, are higher rank or lower rank. It is intended that claimed subject matter include all such embodiments, regarding of convention regarding higher rank or lower rank. Therefore, in some embodiments, higher rank may refer to a higher probability of occurrence of a particular symbol whereas in other embodiments higher rank may refer to a lower probability of occurrence of a particular symbol.

Continuing with this example embodiment, more common symbols, of rank higher than T, for example, may be coded using a variable length coder (VLC), such as a Huffman coder, as one example. Those symbols which are ranked T or lower may be coded by also using a fixed length code.

Therefore, for this particular embodiment, a code for a set of symbols may comprise two-parts: a first variable length set of codes which are coded to be sufficiently unique so that they may be distinguished from each other; and a second fixed length set of codes portion having a number of bits to at least sufficiently to distinguish between a set of higher probability of occurrence symbols and a set of lower probability of occurrence symbols and to distinguish between codes within the set of lower probability of occurrence symbols.

It is noted, of course, that claimed subject matter is not limited to particular embodiments. Therefore, in addition to covering a method of coding of data, claimed subject matter is also intended to cover, for example, software incorporating such a method and to a coder (whether implemented in hardware or software). Claimed subject matter is also intended to include a video or audio codec embodying such a method and/or a video or audio compression system whereby data may be encoded according to a method as described or claimed. For example, embodiments may include transmitting data across a communications channel for reconstruction by a decoder at the far end. Likewise, alternatively, in another embodiment in accordance with claimed subject matter coded data may be stored rather than transmitted. Thus, claimed subject matter is intended to cover these as well as other embodiments, as described in more detail hereinafter.

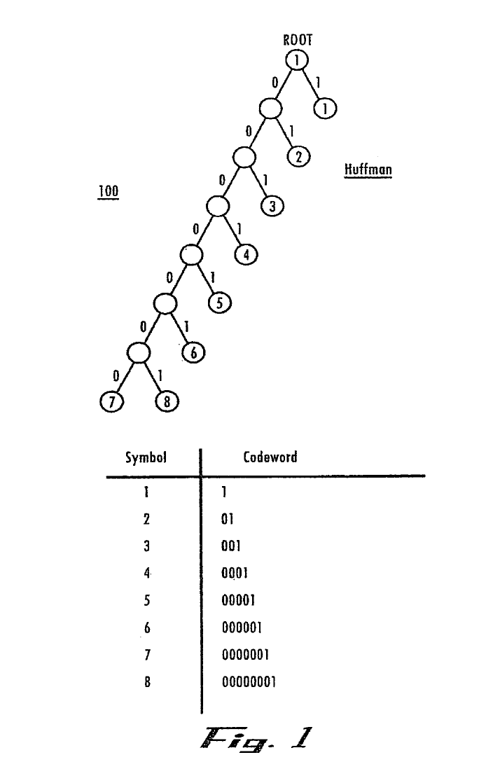

Referring now to FIG. 1, a Huffman code may be determined or constructed by defining a coding tree, in which the probability of occurrence of a symbol is designated as a leaf on the tree. An example or embodiment of such a tree is illustrated in FIG. 1, although, claimed subject matter is not limited in scope to this example or to employing Huffman codes or trees to construct codes, such as Huffman codes. Nonetheless, continuing with this simply example, for purposes of illustration, to form a tree, such as tree 100 in FIG. 1, symbols which occur in the data to be coded are ranked in order of their probabilities. The two lowest probabilities, in this example, are summed to form a new probability and given the binary codes 0 and 1 to distinguish them as two branches splitting from a first node. Their probabilities are added and assigned to that node. Combining of probabilities and prefixing distinguishing binary bits continues along the branches of the tree until the last two probabilities are reached (which, as is well-known, should add to unity).

Using the tree that has not been constructed, a code word, for example, may be formed by locating the leaf containing the particular desired symbol and moving up the branches from the leaf to the root, aggregating the distinguishing binary digits along the way. The aggregate of binary digits thereby forms the code word to be used. Another way of viewing this process is that binary digits 0 and 1 are prefixed to the code as it is constructed, corresponding to the two branches of the tree at node particular nodes traversed on the way up to the root node.

Turning to the example shown in FIG. 1, for example, eight symbols have been “Huffman coded” using this simple binary tree. This tree is termed a binary tree because the nodes have two branches. The symbol are represented by nodes on the tree, with the leftward branch from a node indicating a 0 bit and the rightward branch a 1.

Again, as alluded to above, to generate a code word for a particular symbol, one finds the leaf containing the desired symbol and traverses the tree towards the root, picking up (e.g., prefixing) an additional bit for the traversed branches until the root. To decode, the opposite path is taken, starting at the root and following the path down the tree specified by successive bits in the code until a leaf is reached, where the decoded symbol will be found.

In this simple example, symbols 1 to 8 are representative of actual symbols within a data stream to be sent across a communications channel, or to be stored. As in this example, symbols which occur in a data stream may be ranked in order of their probabilities of occurrence, so that the most frequently occurring symbol, for example, is assigned code word 1, the second most frequently occurring symbol is assigned code word 01 and so on, although, this is merely one possible assignment of code words and claimed subject matter is not limited in scope to this or to any other particular assignment of code words.

If frequencies of occurrence of symbols are known, ranking may be carried out on that basis. If such frequencies are unknown, ranking may be based at least in part on expected or anticipated probabilities. Likewise, due at least in part to the symmetry of the construction, transposition of the roles of symbols 0 and 1 at any node in construction of the tree and formation of codes is equivalent.

Likewise, a tree may be “rebuilt” in response to changing probabilities as coding continues. For example, if the ranking order of occurrences of symbols changes, a better code may be constructed, by rebuilding the tree, for example. Although Huffman Coding is often described in terms of a coding tree, as above, typically, implementation via a binary tree may be less efficient than using tables of probabilities for building a code, and lookup tables for its implementation. Furthermore, the particular code obtained may not necessarily be unique, as the assignment of bits to the branches at a node splitting may be reversed, for example. Also more than two probabilities may be equal, giving an arbitrary choice of symbols to aggregate. Thus, for a particular list of probabilities, several different trees may be equivalent, and these different trees may in some instances be longer or shorter than each other. However, despite these possible tree variations, the Entropy of a Huffman tree built on the same probabilities is the same, and, in general, is the smallest Entropy possible for a VLC.

As is well-known in information theory, the expected “cost” of transmission, in terms of bits transmitted per symbol, may be calculated for any coder. In an alphabet of N symbols, N being a positive integer numeral, with probability of occurrence p(k) of symbol k, the theoretical cost of coding symbol k is log₂ p(k) bits, from which the average cost B of coding a symbol, called the Entropy of the source of the symbols, is obtained by weighting the symbol costs by their probabilities as follows:

$$B = - {\sum }_{k = 1}^{N} p ( k ) {log}_{2} p ( k ) bits$$

A simple coder, for example, might assign k bits to communicate symbol k. This is one example of a Variable Length Code (VLC), which might or might not comprise a Huffman code. In this example, the theoretical cost of sending a message by this particular code is

$$B = - {\sum }_{k = 1}^{N} kp ( k )$$

### Furthermore, if the probability of symbol k is exactly ½^{k}, then log₂p(c)=−k and this code in this particular case achieves exactly the theoretical cost.

Likewise, it turns out that if symbol k has probability ½^{k}, the code produced is the Huffman code described in the example above, as illustrated in FIG. 1.

The Entropy of a Huffman code, in general, is the lowest Entropy of any VLC that may be employed, although it will not always achieve the theoretical cost; that happens if the probability of symbol k is ½^{k}, such as in the case cited above. It is also not necessarily the most efficient code among all codes. For example, a Golomb code, which is also quite simple, but is not a VLC, may at times be more efficient as is shown in the examples below. Another family of coding methods, referred to here as arithmetic codes, has the ability to approach the theoretical cost, and therefore may be more efficient than the Huffman code, although such codes may be complex and challenging to tune for this goal.

One disadvantage associated with a Huffman code is that the codes for infrequent symbols in a large alphabet may be long. An occurrence of such symbols in a short message may, at times, be disruptive. For example, in image compression, at a relatively high compression ratios, a Huffman code of some symbols used to code an image block may be greater than the “budget” for the block, creating a situation in which the block cannot be coded, or in which bits from other parts of the image are allocated to the particular block, thus affecting image quality in the parts of the image from which such bits are allocated. Likewise, in practice (particularly if adaptive), the construction of the tree may be from probabilities that are estimated from data as it arises from a source of symbols. In other words, probabilities are estimated, so opportunities to construct a short code may be overlooked due at least in part to potential errors in the estimate.

Embodiments in accordance with claimed subject matter may address at least in part some of the previously described technical issues while also allowing a code to be adaptive and/or efficient. In one particular embodiment, for example, based at least in part on particular probabilities, a certain number of less frequently occurring symbols may not be coded by a VLC and may, instead, employ a same number of bits. Although not required, at times it may be desirable that this number be a power of 2.

Suppose, for example, with N symbols, arranged in descending order of probability, for example, and having a threshold, T, in the range 1 to N, symbols 1 to T−1 are coded by a VLC. The remaining N−T+1 of those symbols, in this example, numbered T to N, may be coded by a fixed length code whose length is sufficient to code the remaining symbols, but because it is fixed will not be as long as the longest VLC that might otherwise be used. It is combined with a sequence of bits, e.g., a code, indicating that the particular symbol is not in the range 1 to T−1. Thus, this approach reduces the potential disruption mentioned above in connection with Huffman codes.

Below an example is provided involving a Huffman coder in which it is known to be optimal, meaning, in this context, that the actual code will on average achieve the theoretical entropy. In this example, probabilities of the 8 symbols are assigned as ½, ¼, . . . so that the theoretical entropy of a stream of symbols is 1.9844 bits per symbol. A Huffman coder in such a situation on average achieves this precisely.

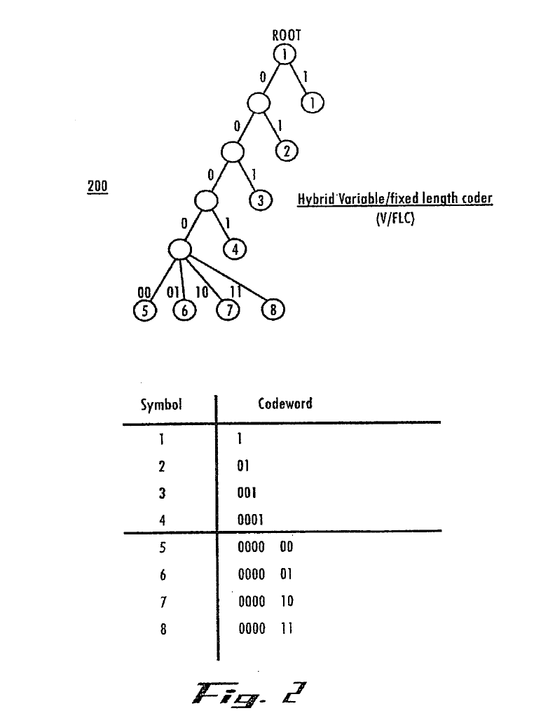

However, an example embodiment is shown in FIG. 2 in which a threshold of T=5 has been used. Thus, as explained above for this embodiment, in this particular example, the last four symbols are coded by postfixing two bits to a special initial code (here, 0000). The initial code signals to a decoder that these symbols have not been VLC coded. It will be understood, of course, that a special prefixed code may comprise anything convenient for the purposes of signalling if it does not create ambiguity for a decoder with respect to distinguishing fixed length codes from possible VLC codes that might be used.

The upper part of FIG. 2 shows a tree structure representing this particular coding scheme; although, this is merely an illustrative example and claimed subject matter is not limited in scope to this particular example. Nonetheless, in this example, symbols 1 to 4 are coded by a VLC as before, but symbols 5 to 8 all emanate from a common node, as shown. The links or branches to that node may be considered as representative of a fixed length two-bit code which identifies the final symbols, namely 00, 01, 10 and 11, again as shown. As before, to generate a code word for a particular symbol, one traverses the tree from the root to the leaf node that represents that symbol.

In the example shown, the code 0000 arises from the structure of the tree. So, the initial part of the code 0000 may be read as an instruction to traverse the tree from the root, travelling four levels down the 0 links. The desired leaf may then be reached by following the appropriate remaining link or branch, namely 00, 01, 10, or 11.

More generally, the initial part of the code word for the symbols that are ranked T or lower, indicating here low probability of occurrence, is representative of those links of the tree that are traversed to reach a final node from which leaves associated with relatively low-frequency symbols branch off. In another embodiment (not shown), low-frequency symbols might, for example, branch from node labelled 4 in FIG. 2, in which case the initial part of a fixed length code word may comprise 0001 rather than 0000.

Of course, the precise form of such a code may vary. However, it is desirable that a decoder have the ability to recognize a special code, such as indicating, for example, that a fixed length code is to follow. Furthermore, in an implementation, a look-up table may provide convenience and other potential advantages relative to a tree traversal approach, although which is more desirable may depend on a variety of differing factors, including, at least in part, the particular application or situation.

Recalling that, in this example, symbol probabilities are: ½, ¼ and so on, the following table may be constructed to compare the average number of bits used per symbol in this example embodiment with the average number of bits used per symbol for the Huffman code of FIG. 1:

| Sym | Prob | Code | Total Bits | Av Bits | Huff Code | Av Bits Huff |
|---|---|---|---|---|---|---|
| 1 | ½ | 1 | 1 | ½ | 1 | ½ |
| 2 | ¼ | 01 | 2 | 2/4 | 01 | 2/4 |
| 3 | ⅛ | 001 | 3 | ⅜ | 001 | ⅜ |
| 4 | 1/16 | 0001 | 4 | 4/16 | 0001 | 4/16 |
| 5 | 1/32 | 0000 00 | 6 | 6/32 | 00001 | 5/32 |
| 6 | 1/64 | 0000 01 | 6 | 6/64 | 000001 | 6/64 |
| 7 | 1/128 | 0000 10 | 6 | 6/128 | 0000001 | 7/128 |
| 8 | 1/256 | 0000 11 | 6 | 6/256 | 0000000 | 7/256 |

Note that the example embodiment, here, is less efficient for symbol 5, but more efficient for symbols 7 and 8. These last two occur infrequently. Overall, as a result, this example embodiment is less efficient than the Huffman code that may be employed here, but only slightly.

The average number of bits used by this hybrid Variable/Fixed Length Code (V/FLC) is 2.0. This is less than 1% worse than the Huffman code, here at 1.9844. However, this value is the optimum case for Huffman. It is seen that threshold symbol T, here symbol 5, is worse than the Huffman coder. However, for rarer symbols, the code is shorter. The rarer symbols, thus, are coded more efficiently and with a shorter code in this example.

If a VLC for symbols k from 1 to T−1 is k bits long, the theoretical cost in bits per symbol of such a V/FLC may be represented as:

$$B = - {\sum }_{k = 1}^{T - 1} kp ( k ) - \text{\{} T - 1 + ceil ( {log}_{2} ( N - T ) \} {\sum }_{k = T}^{N} p ( k )$$

In one alternate embodiment, a Huffman procedure may be applied to construct a VLC for the first T−1 symbols, or apply any other VLC process, whether such VLC process is currently known or to be later developed in the future. In using a Huffman procedure, we may aggregate the N−T+1 symbols T to N (and their probabilities) to be distinguished by a fixed length number of bits, for example. If N−T+1 is a power of 2, then as is well-known they can be enumerated by all possible combinations of log₂(N−Td−1) bits, usually but not necessarily, by counting them in order to obtain a binary number. Put another way, the code is efficient because no binary number is unused.

Embodiments in accordance with claimed subject matter may be used in a variety of applications, and is not restricted by the information content of the symbols that are to be coded. The symbols may, for example, represent text characters, pixel values within a still or moving image, amplitudes within an audio system, and/or other possible values or attributes. In another embodiment, a method in accordance with claimed subject matter may provide a basis for a run length coder. An embodiment may also be used for encoding streams of binary data, such as where the symbols are represented by a series of bits, for example, and other potential variations.

Embodiments in accordance with claimed subject matter may be applied to coding of data of all types, including non-numeric data, such as symbolic data, for example, converted into numerical form by any convenient mapping prior to application of coding. As is noted, embodiments perform well for run length coding, although it will, of course, be understood that claimed subject matter is not limited to that application. It is intended that embodiments of claimed subject matter be applied to any one of a number of different types of data coding. Therefore, claimed subject matter is not intended to be limited in terms of the type of data to which it may be applied.

It will, of course, be understood that, although particular embodiments have just been described, the claimed subject matter is not limited in scope to a particular embodiment or implementation. For example, one embodiment may be in hardware, such as implemented to operate on a device or combination of devices, for example, whereas another embodiment may be in software. Likewise, an embodiment may be implemented in firmware, or as any combination of hardware, software, and/or firmware, for example. Likewise, although claimed subject matter is not limited in scope in this respect, one embodiment may comprise one or more articles, such as a storage medium or storage media. This storage media, such as, one or more CD-ROMs and/or disks, for example, may have stored thereon instructions, that when executed by a system, such as a computer system, computing platform, or other system, for example, may result in an embodiment of a method in accordance with claimed subject matter being executed, such as one of the embodiments previously described, for example. As one potential example, a computing platform may include one or more processing units or processors, one or more input/output devices, such as a display, a keyboard and/or a mouse, and/or one or more memories, such as static random access memory, dynamic random access memory, flash memory, and/or a hard drive.

In the preceding description, various aspects of claimed subject matter have been described. For purposes of explanation, specific numbers, systems and/or configurations were set forth to provide a thorough understanding of claimed subject matter. However, it should be apparent to one skilled in the art having the benefit of this disclosure that claimed subject matter may be practiced without the specific details. In other instances, well known features were omitted and/or simplified so as not to obscure the claimed subject matter. While certain features have been illustrated and/or described herein, many modifications, substitutions, changes and/or equivalents will now occur to those skilled in the art. It is, therefore, to be understood that the appended claims are intended to cover all such modifications and/or changes as fall within the true spirit of claimed subject matter.

1. A method of coding an alphabet of N symbols for storage and/or transmission by a computing platform, the alphabet of N symbols ranked by expected probability of occurrence, the method comprising:
assigning a threshold probability T;
coding symbols which have a higher probability of occurrence than the threshold probability T with a variable length code; and
coding symbols which have a probability of occurrence substantially the same as or lower than the threshold probability with a fixed length code.

2. The method of claim 1, wherein the variable length code comprises a Huffman code.

3. The method of claim 1, wherein the fixed length code comprises: a first code which differs from any possible code for a symbol having a higher probability of occurrence than the threshold probably T, followed by, a second code which uniquely identifies a given symbol from the threshold probability T and from any other symbol having a probability of occurrence lower than the threshold probability T.

4. The method of claim 1, wherein the coding comprises binary coding.

5. The method of claim 4, wherein the fixed length code comprises: a first code which differs from any possible code for a symbol having a higher probability of occurrence than the threshold probability T, followed by, a second code indicative of a binary representation of a numeral in the range 1 to N−T.

6. The method of claim 5, wherein the first code comprises a sequence of zeros and/or ones.

7. The method of claim 6, wherein N−T+1 is chosen to be a power of two.

8. The method of claim 1, for coding a stream of binary data, wherein the symbols are represented by a series of bits.

9. The method of claim 1, wherein the symbols are represented using a length of a run.

10. A storage medium having stored thereon instructions that, if executed by a computing platform, result in performance of a method of coding an alphabet of N symbols for storage and/or transmission by the computing platform, the alphabet of N symbols ranked by expected probability of occurrence, the method comprising:
assigning a threshold probability T;
coding symbols which have a higher probability of occurrence than the threshold probability T with a variable length code; and
coding symbols which have a probability of occurrence substantially the same as threshold probability or lower with a fixed length code.

11. The storage medium of claim 10, wherein said instructions, if executed, further result in the variable length code comprising a Huffman code.

12. The storage medium of claim 10, wherein said instructions, if executed, further result in the fixed length code comprising: a first code which differs from any possible code for a symbol having a higher probability of occurrence than the threshold probably T, followed by, a second code which uniquely identifies a given symbol from the threshold probability T and from any other symbol having a probability of occurrence lower than the threshold probability T.

13. The storage medium of claim 10, wherein said instructions, if executed, further result in the coding comprising binary coding.

14. The storage medium of claim 13, wherein said instructions, if executed, further result in the fixed length code comprising: a first code which differs from any possible code for a symbol having a higher probability of occurrence than the threshold probability T, followed by, a second code indicative of a binary representation of a numeral in the range 1 to N−T.

15. The storage medium of claim 14, wherein said instructions, if executed, further result in the first code comprising a sequence of zeros and/or ones.

16. The storage medium of claim 15, wherein said instructions, if executed, further result in N−T+1 being chosen to be a power of two.

17. The storage medium of claim 10, wherein said instructions, if executed, further result in, for coding a stream of binary data, the symbols being represented by a series of bits.

18. The storage medium of claim 10, wherein said instructions, if executed, further result in the symbols being represented using a length of a run.

19. An apparatus comprising:
means, for an alphabet of N symbols ranked by expected probability of occurrence, for assigning a threshold probability T;
means for coding symbols which have a higher probability of occurrence than the threshold probability T with a variable length code; and
means for coding symbols which have a probability of occurrence substantially the same as threshold probability or lower with a fixed length code.

20. The apparatus of claim 19, wherein, said means for coding symbols with a variable length code comprises means for coding symbols with a Huffman code.

21. The apparatus of claim 19, wherein the fixed length code to be coded comprises: a first code which differs from any possible code for a symbol having a higher probability of occurrence than the threshold probably T, followed by, a second code which uniquely identifies a given symbol from the threshold probability T and from any other symbol having a probability of occurrence lower than the threshold probability T.

22. The apparatus of claim 19, wherein the coding comprises binary coding.

23. The apparatus of claim 22, wherein the fixed length code to be coded comprises: a first code which differs from any possible code for a symbol having a higher probability of occurrence than the threshold probability T, followed by, a second code indicative of a binary representation of a numeral in the range 1 to N−T.

24. The apparatus of claim 23, wherein the first code to be coded comprises a sequence of zeros and/or ones.

25. The apparatus of claim 24, wherein N−T+1 is to be chosen to be a power of two.

26. The apparatus of claim 19, for coding a stream of binary data, wherein the symbols are to be represented by a series of bits.

27. The apparatus of claim 19, wherein the symbols are represented using a length of a run.

28. A computer platform configured to code an alphabet of N symbols for storage and/or transmission by said platform, said platform adapted to: for an alphabet of N symbols ranked by expected probability of occurrence, assign a threshold probability T, code symbols which have a higher probability of occurrence than the threshold probability T with a variable length code, and code symbols which have a probability of occurrence substantially the same as threshold probability or lower with a fixed length code.

29. The computer platform of claim 28, the variable length code comprises a Huffman code.

30. The computer platform of claim 28, wherein the fixed length code comprises: a first code which differs from any possible code for a symbol having a higher probability of occurrence than the threshold probably T, followed by, a second code which uniquely identifies a given symbol from the threshold probability T and from any other symbol having a probability of occurrence lower than the threshold probability T.

31. The computer platform of claim 28, wherein said computing platform is further adapted to code symbols using binary coding.

32. The computer platform of claim 31, wherein the fixed length code comprises: a first code which differs from any possible code for a symbol having a higher probability of occurrence than the threshold probability T, followed by, a second code indicative of a binary representation of a numeral in the range 1 to N−T.

33. The computer platform of claim 32, wherein the first code comprises a sequence of zeros and/or ones.

34. The computer platform of claim 33, wherein a value of N−T+1 is chosen to be a power of two.

35. The computer platform of claim 28, wherein said computing platform is further adapted, for coding a stream of binary data, so that the symbols are represented by a series of bits.

36. The computer platform of claim 28, wherein said computing platform is further adapted so that the symbols are represented using a length of a run.
